(19) United States
(12) Patent Application Publication
(10) Pub. No.: US 2026/0344546 A1
(43) Pub. Date: Oct. 29, 2026

(54) POWER MODULE

(71) Applicant: SENTEC E&E CO., LTD., Taoyuan City (TW)

(72) Inventors: Kun-Tzu Chen, Taoyuan City (TW); Chun-Hung Lin, Taoyuan City (TW); Pei-Ching Yen, Taoyuan City (TW); Chun-Ming Wei, Taoyuan City (TW)

(73) Assignee: SENTEC E&E CO., LTD., Taoyuan City (TW)

(21) Appl. No.: 19/453,381

(22) Filed: Jan. 20, 2026

Related U.S. Application Data
(60) Provisional application No. 63/792,934, filed on Apr. 23, 2025.

(30) Foreign Application Priority Data
Oct. 15, 2025 (TW) 114139866

(51) Int. Cl. H10W 90/00; H10W 40/20; H10W 70/40

(52) U.S. Cl. CPC H10W 90/811; H10W 40/20; H10W 70/466; H10W 70/479; H10W 70/481

(57) ABSTRACT

A power module includes a substrate, a lead frame, and a plurality of power transistor dies. The substrate includes a thermal conductive layer, an insulating layer, and a conductive layer. The insulating layer is located between the thermal conductive layer and the conductive layer. Each of the power transistor dies includes a first electrode pattern and a second electrode pattern opposite from the first electrode pattern. The first electrode pattern is coupled to the conductive layer, and the second electrode pattern is coupled to the lead frame, thereby connecting the power transistor dies in parallel.

### CROSS-REFERENCE TO RELATED APPLICATION

This application claims the benefit of US provisional application serial No., 63/792,934 filed on April 23, 2025 and claims the priority of Patent Application No. 114139866 filed in Taiwan, R.O.C. on October 15, 2025. The entirety of the above-mentioned patent applications are hereby incorporated by references herein and made a part of the specification.

### BACKGROUND

### Technical Field

The present invention relates to power semiconductor technology, and in particular, to a power module.

### Related Art

Currently, there are only single power semiconductor devices available on the market. Users need to connect a plurality of power semiconductor devices in parallel on their own to assemble a circuit useful for high-current environments, and also need to additionally assemble gate resistors required for each of the power semiconductor devices on their own. Furthermore, thermal dissipation surfaces of the power semiconductor devices in the market all face towards a circuit board on which the power semiconductor devices are installed, thereby causing the heat from the power semiconductor devices to be accumulated on the circuit board and thus the heat cannot be effectively dissipated. Furthermore, as the market demand for enhancing output power becomes increasingly urgent, conventional structures are struggling to support thermal dissipation and current-carrying capacity, making it difficult for power semiconductor devices to operate reliably under high-power conditions. Therefore, there is an urgent need for new solutions.

### SUMMARY

In view of the above, the present invention provides a power module. A power

module includes a substrate, a lead frame, and a plurality of power transistor dies. The substrate includes a thermal conductive layer, an insulating layer, and a conductive layer. The insulating layer is located between the thermal conductive layer and the conductive layer. Each of the power transistor dies includes a first electrode pattern and a second electrode pattern opposite from the first electrode pattern. The first electrode pattern is coupled to the conductive layer, and the second electrode pattern is coupled to the lead frame, thereby connecting the power transistor dies in parallel.

To sum up, according to some embodiments, a plurality of power transistor dies connected in parallel are integrated into a single power module, so as to save the assembly burden and enhance the stability of high current transmission. In some embodiments, the thermal conductive layer of the present invention can be far away from a circuit board on which the power module is installed, so as to avoid that the heat is accumulated on the circuit board, thereby achieving effective thermal dissipation and lowering the risk of damage of the power module. In some embodiments, the thermal conductive layer is isolated from the conductive layer by the insulating layer in the present invention, so as to achieve the thermoelectric separation effect, thereby lowering the risk of signals being affected.

### BRIEF DESCRIPTION OF THE DRAWINGS

FIG. 1 is a perspective view of a power module according to some embodiments of the present invention;

FIG. 2 is a schematic diagram of a power transistor die according to some embodiments of the present invention;

FIG. 3 is a bottom perspective view of a power module according to some embodiments of the present invention;

FIG. 4 is a bottom view of a power module with a lead frame removed according to some embodiments of the present invention;

FIG. 5 is a schematic view of a power module taken along line A-A' according to some embodiments of the present invention;

FIG. 6 is an equivalent circuit diagram of a power module according to some

embodiments of the present invention;

FIG. 7 is a schematic view of a power module according to some embodiments of the present invention;

FIG. 8 is a bottom view of a power module according to some embodiments of the present invention; and

FIG. 9 is an application diagram of a power module according to some embodiments of the present invention.

### DETAILED DESCRIPTION

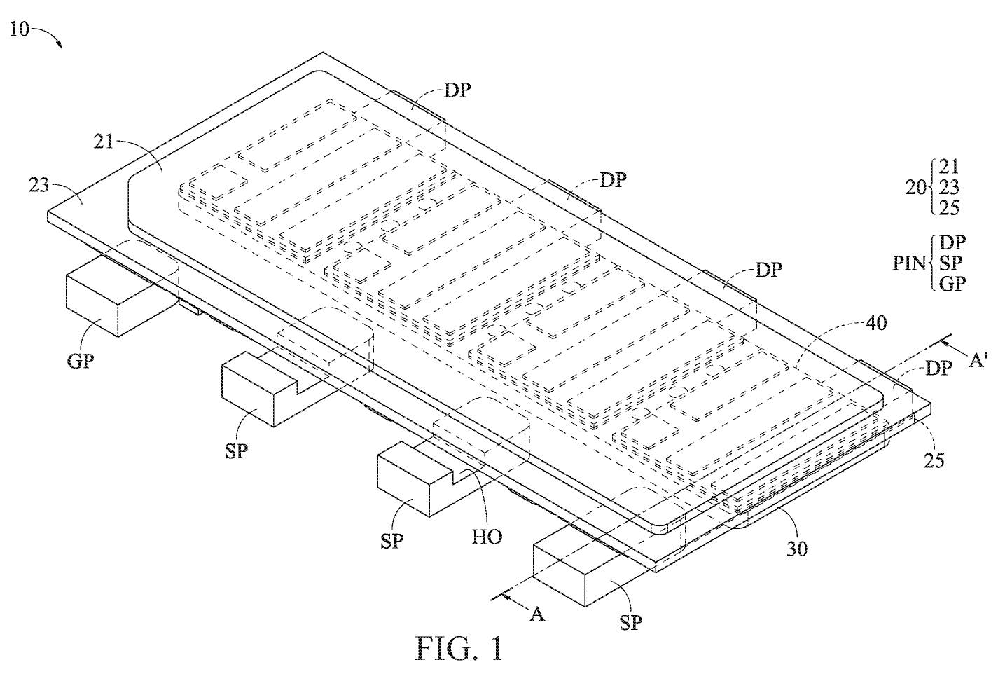

Referring to FIG. 1, FIG. 1 is a perspective view of a power module 10 according to some embodiments of the present invention. The power module 10 includes a substrate 20, a lead frame 30, and a plurality of power transistor dies 40. The substrate 20 includes a thermal conductive layer 21, an insulating layer 23, and a conductive layer 25. The thermal conductive layer 21 is configured to transfer the heat energy of the power module 10. The conductive layer 25 is configured to transmit signals of elements (e.g., the power transistor dies 40) of the power module 10. The insulating layer 23 is configured to isolate the thermal conductive layer 21 from the conductive layer 25, that is, the thermoelectric separation effect is achieved, thereby lowering the risk of signals being affected. The insulating layer 23 is, for example, a ceramic layer. The thermal conductive layer 21 and the conductive layer 25 are each, for example, a metal layer. That is, the substrate 20 is, for example, a ceramic substrate, and the thermal conductive layer 21 and the conductive layer 25 are metal layers located on two opposite surfaces of the ceramic substrate.

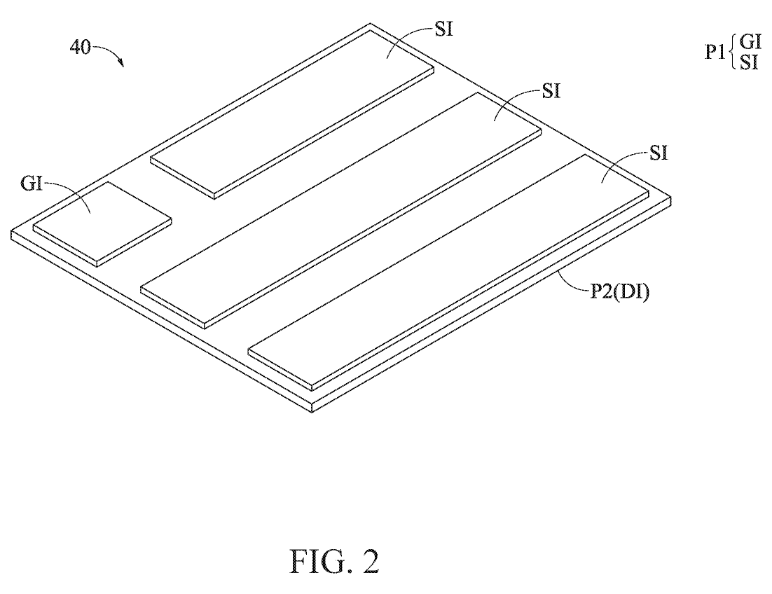

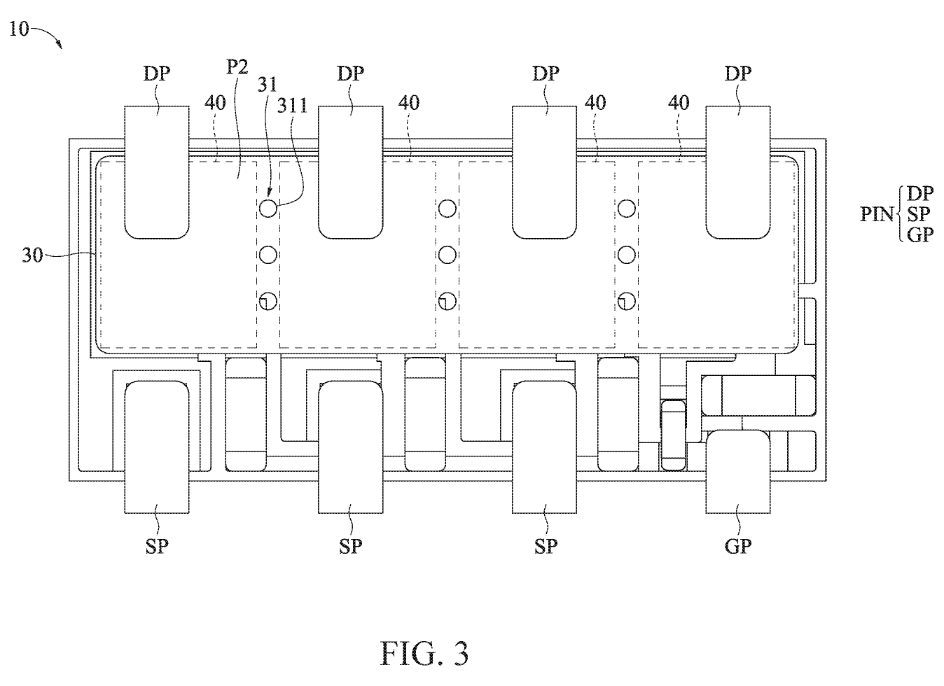

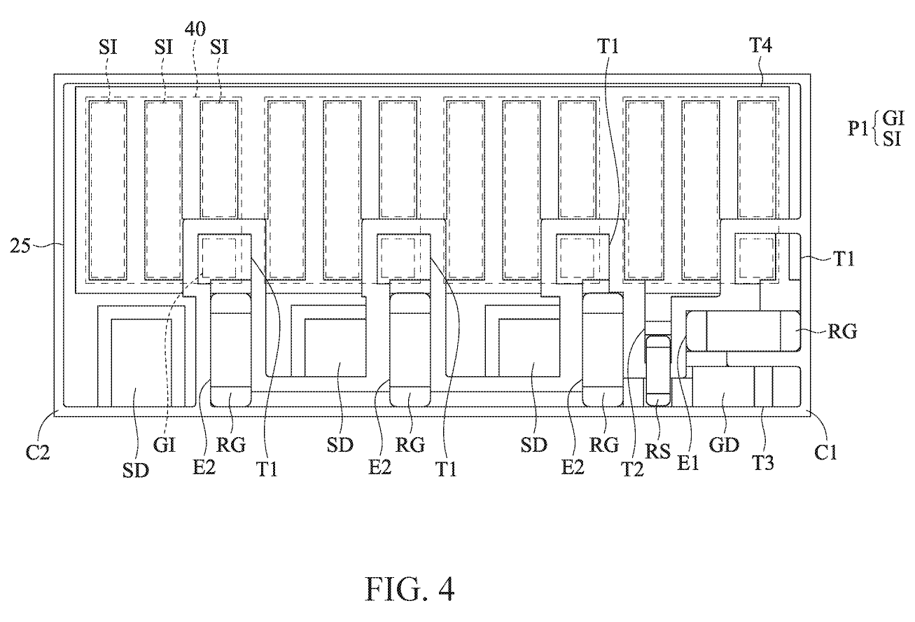

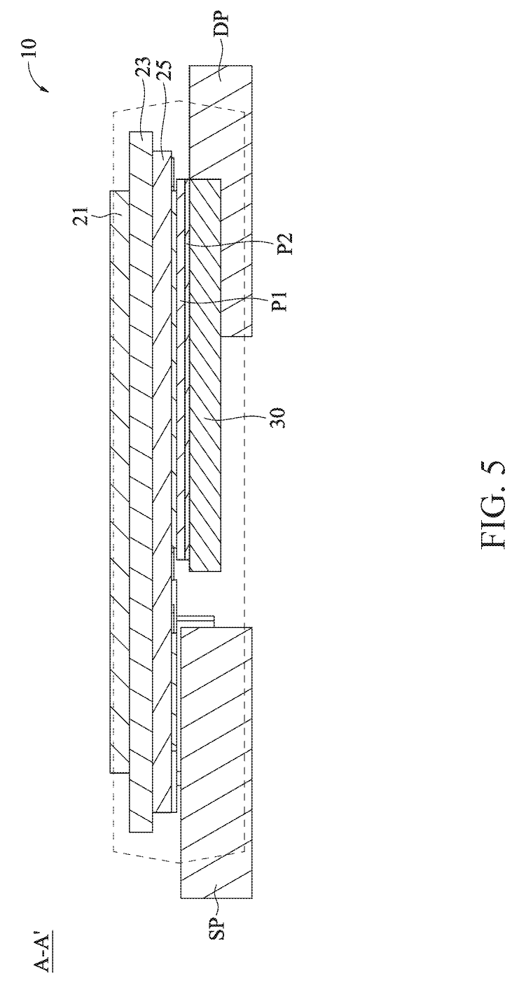

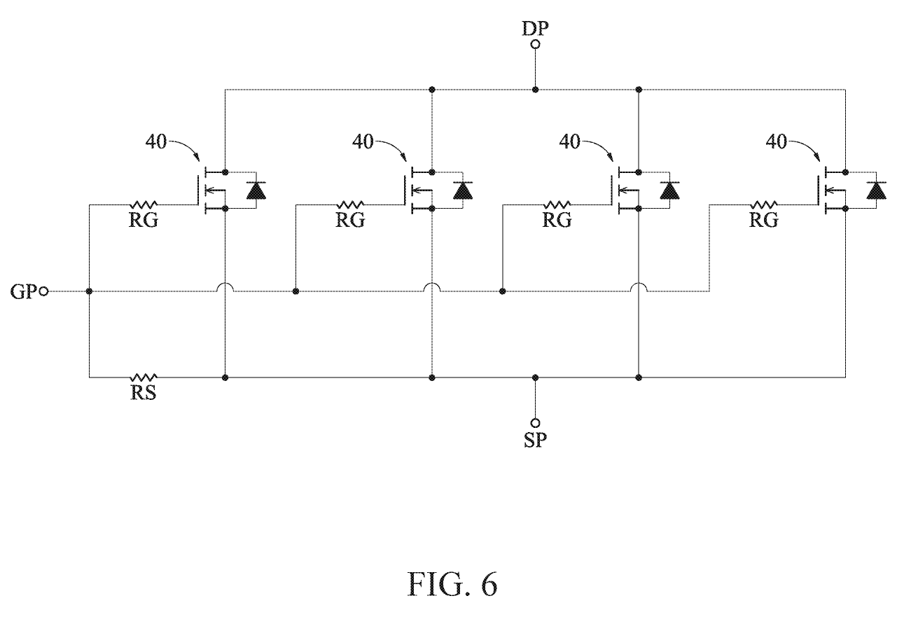

References are made to FIG. 2 through FIG. 6. FIG. 2 is a schematic diagram of a power transistor die 40 according to some embodiments of the present invention. FIG. 3 is a bottom perspective view of a power module 10 according to some embodiments of the present invention. FIG. 4 is a bottom view of a power module 10 with a lead frame 30 removed according to some embodiments of the present invention. FIG. 5 is a schematic view of a power module 10 taken along line A-A' according to some embodiments of the present invention. FIG. 6 is an equivalent circuit diagram of a power module 10 according to some embodiments of the

present invention. Four power transistor dies 40 are illustrated here, but the present invention is not limited to this. The power transistor dies 40 can be arranged according to the needs of users. As shown in FIG. 2, each of the power transistor dies 40 includes a first electrode pattern P1 and a second electrode pattern P2 opposite from the first electrode pattern. Specifically, each of the power transistor dies 40 includes two opposite surfaces (e.g., a first surface and a second surface). The first electrode pattern P1 is located on the first surface, and the second electrode pattern P2 is located on the second surface. As shown in FIG. 3 and FIG. 4, the first electrode pattern P1 is coupled to the conductive layer 25, and the second electrode pattern P2 is coupled to the lead frame 30, thereby connecting the power transistor dies 40 in parallel. That is, as shown in FIG. 5, internal elements of the power module 10 are sequentially arranged from top to bottom: the thermal conductive layer 21, the insulating layer 23, the conductive layer 25, the first electrode pattern P1, the second electrode pattern P2, and the lead frame 30. Specifically, as shown in FIG. 6, sources of the power transistor dies 40 are commonly connected, and drains of the power transistor dies 40 are commonly connected, thereby connecting the power transistor dies 40 in parallel. Thus, the power transistor dies 40 connected in parallel can be integrated into a single power module 10, so as to save the assembly burden and enhance the stability of high current transmission. In some embodiments, the power transistor die 40 is achieved via flip-chip technology, in which the first electrode pattern P1 is coupled to the conductive layer 25, and the second electrode pattern P2 is coupled to the lead frame 30.

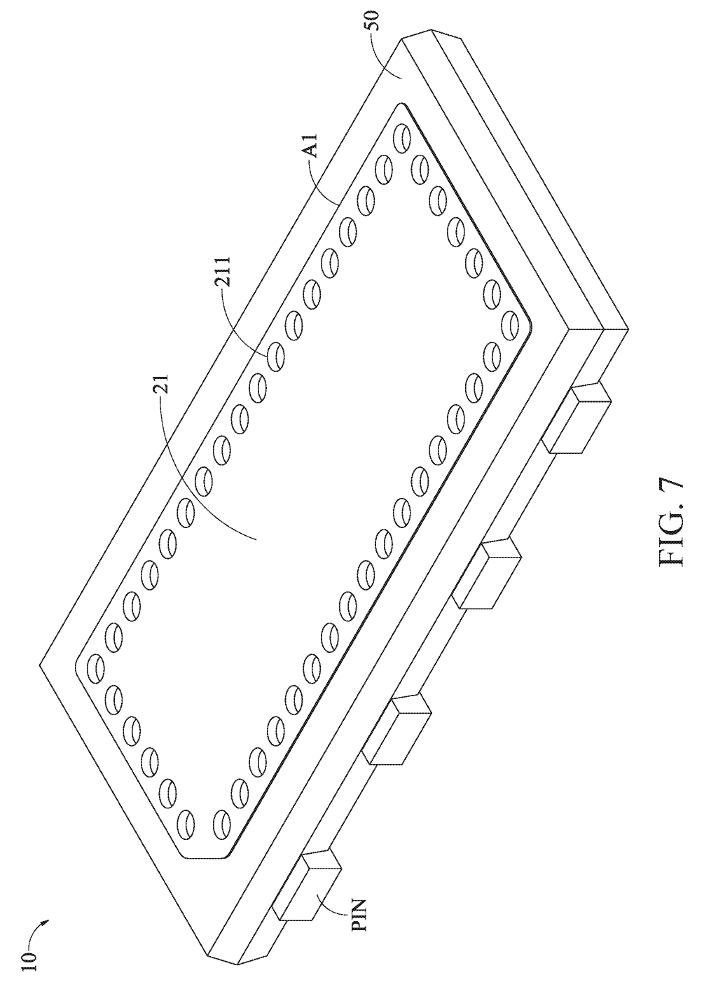

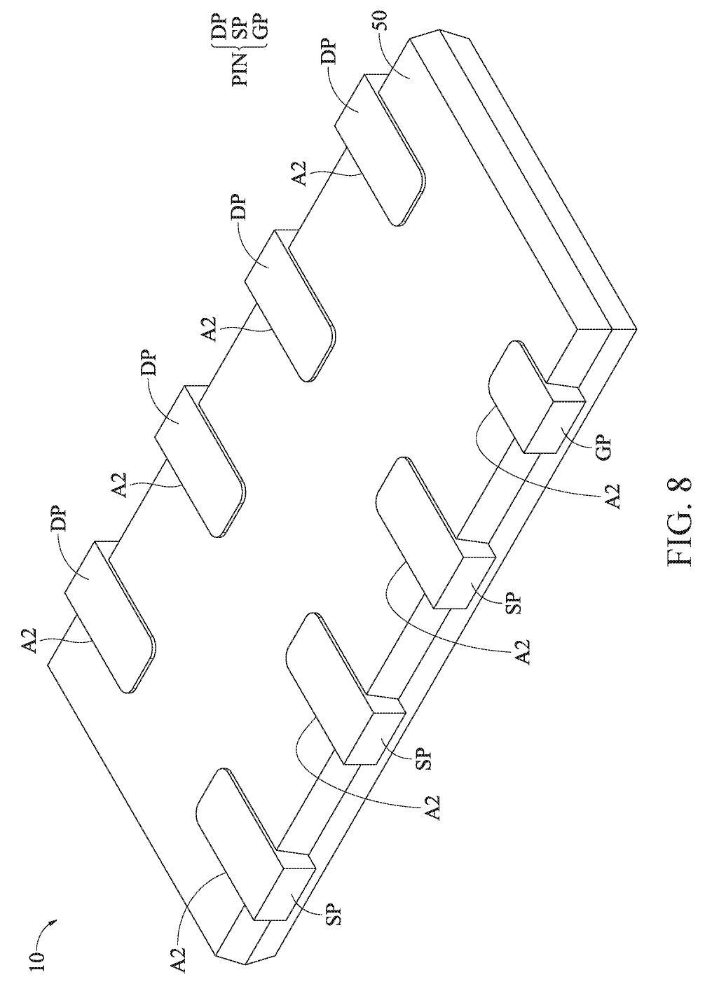

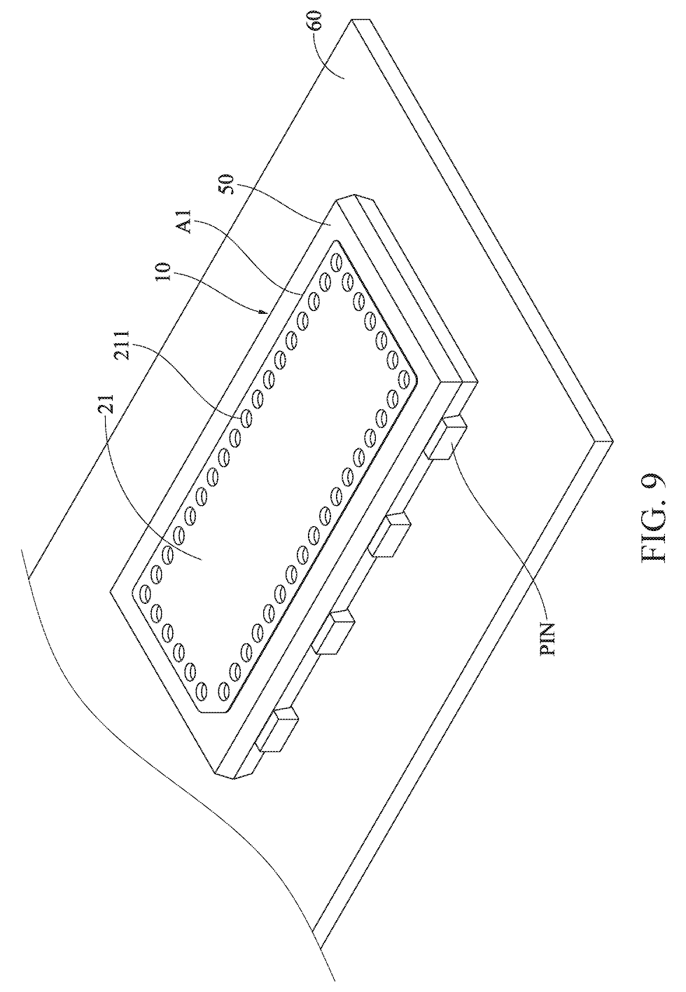

References are made to FIG. 7 through FIG. 9. FIG. 7 is a schematic view of a power module 10 according to some embodiments of the present invention. FIG. 8 is a bottom view of a power module 10 according to some embodiments of the present invention. FIG. 9 is an application diagram of a power module 10 according to some embodiments of the present invention. In some embodiments, the power module 10 further includes a package 50. The substrate 20, the lead frame 30, and the power transistor dies 40 are encapsulated within the package 50. The package 50 includes a first exposed area A1. The thermal conductive layer 21 is exposed through the first exposed area A1. The power module 10 is disposed on a circuit board 60, and the thermal conductive layer 21 exposed through the first exposed area A1 is far away from the circuit board 60. The package 50 will limit the transmission direction of heat energy, so that the heat energy can be transmitted to the thermal conductive layer 21, and since

the thermal conductive layer 21 is far away from the circuit board 60, the heat will not be accumulated on the circuit board 60, thereby achieving effective thermal dissipation and lowering the risk of damage of the power module 10. In some embodiments, the thermal conductive layer 21 may be in contact with a thermal dissipation device (e.g., a water-cooled thermal fin), so as to enhance the thermal dissipation effect.

As shown in FIG. 8, in some embodiments, the power module 10 further includes a plurality of external pins PIN. The package 50 includes a second exposed area A2 opposite to the first exposed area A1, so as to expose the external pins PIN. The external pins PIN are coupled to the circuit board 60. Thus, the heat can be dissipated not only through the thermal conductive layer 21, but also through the external pins PIN. That is, the present invention can realize two-way thermal dissipation.

As shown in FIG. 2, in some embodiments, the first electrode pattern P1 of each power transistor die 40 includes a gate conductive island GI, so as to represent a gate of the power transistor die 40. As shown in FIG. 4 and FIG. 6, in some embodiments, the power module 10 further includes a plurality of gate resistors RG. The gate resistors RG are in one-to-one correspondence with the power transistor dies 40, that is, the number of the gate resistors RG corresponds to that of the power transistor dies 40. Each gate resistor RG is coupled to the conductive layer 25, so as to be connected in series with the gate conductive island GI of the first electrode pattern P1 of the corresponding power transistor die 40. That is, each gate resistor RG is connected in series with the gate of the corresponding power transistor die 40. The gate resistors RG are commonly connected to each other via the conductive layer 25.

As shown in FIG. 2, in some embodiments, the first electrode pattern P1 of each power transistor die 40 further includes at least one source conductive island SI, so as to represent a source of the power transistor die 40. As illustrated here, the first electrode pattern P1 of the single power transistor die 40 has three source conductive islands SI, but the present invention is not limited to this. The number of the source conductive islands SI of the first electrode pattern P1 of the single power transistor die 40 can be adjusted according to the needs of users. As shown in FIG. 4 and FIG. 6, in some embodiments, the ground resistor RS is coupled to the conductive layer 25, so as to be connected in series with the source conductive

island SI of the first electrode pattern P1 of one of the power transistor dies 40. That is, the ground resistor RS is connected in series with the source of one of the power transistor dies 40. The ground resistor RS and the gate resistors RG are commonly connected to each other via the conductive layer 25. The ground resistor (also called a reverse leakage suppression resistor) RS can provide a high-resistance stable path when the power transistor dies 40 are turned off, so as to avoid floating, and false turn-on can be suppressed, the voltage sharing between the power transistor dies 40 can be improved, and the reliability risk of leakage current under high voltage can be lowered.

As shown in FIG. 4, specifically, the conductive layer 25 includes a plurality of traces (e.g., a plurality of first traces T1, second traces T2, third traces T3, and fourth traces T4, etc. The gate resistors RG, the power transistor dies 40, and the first traces T1 are in one-to-one correspondence, that is, the number of the gate resistors RG, the number of the power transistor dies 40, and the number of the first traces T1 correspond to each other). Each gate resistor RG is coupled to the gate conductive island GI of the first electrode pattern P1 of the corresponding power transistor die 40 via one of the first traces T1. The ground resistor RS is coupled to the source conductive island SI of the first electrode pattern P1 of one of the power transistor dies 40 via the second trace T2. The ground resistor RS and the gate resistors RG are coupled to the third trace T3, so that the ground resistor RS and the gate resistors RG are commonly connected to each other. The source conductive island SI of the first electrode pattern P1 of each of the power transistor dies 40 is coupled to the fourth trace T4, that is, the sources of all of the power transistor dies 40 are commonly connected to each other via the fourth trace T4.

As shown in FIG. 4, in some embodiments, the third trace T3 extends along a first edge of the substrate 20, and the first trace T1 and the second trace T2 extend from the power transistor die 40 toward the third trace T3. The fourth trace T4 extends along a second edge of the substrate 20 opposite to the first edge. In some embodiments, the third trace T3 has a first extension E1, and the first extension E1 extends toward the power transistor die 40 and is located between the second trace T2 and the first trace of the first traces T1 adjacent to a first corner C1 of the substrate 20, so as to be coupled to the gate resistor RG coupled to the first trace of the first traces T1 adjacent to the first corner C1 of the substrate 20. The third trace T3

also has a plurality of second extensions E2 each extending toward the rest of the first traces T1, so as to be coupled to the rest of the gate resistors RG.

As shown in FIG. 4, FIG. 6, and FIG. 8, in some embodiments, the external pins PIN include a gate pin GP. The conductive layer 25 includes a gate pin pad GD. The gate pin pad GD is located at the first corner C1 of the substrate 20 and coupled to the gate pin GP and the third trace T3. That is, the gate pin GP, the ground resistor RS, and the gate resistors RG are commonly connected to each other. In some embodiments, the third trace T3 extends from the first corner C1 along the first edge of the substrate 20 toward a second corner C2 of the substrate 20 opposite to the first corner C1.

As shown in FIG. 4, FIG. 6, and FIG. 8, in some embodiments, the external pins PIN include a plurality of source pins SP. Three source pins SP are illustrated here, but the present invention is not limited to this. The number of the source pins SP can be adjusted according to the needs of users. The conductive layer 25 includes a plurality of source pin pads SD in one-to-one correspondence with the source pins SP. The source pin pads SD are coupled to the source pins SP and the source conductive island SI of each of the first electrode patterns P1 of some of the power transistor dies 40. One of the source pin pads SD is located at the second corner C2 of the substrate 20, and the rest of the source pin pads SD are located between the third trace T3 and the power transistor dies 40. Specifically, the source pin pads SD are coupled to the source pins SP, and coupled to the source conductive island SI of each of the first electrode patterns P1 of some of the power transistor dies 40 via the fourth trace T4. In some embodiments, one of the rest of the source pin pads SD is arranged between the second extensions E2 of every two third traces T3.

As shown in FIG. 1 and FIG. 4, in some embodiments, each of the source pins SP coupled to the rest of the source pin pads SD has a recess HO, so as to cross over the third trace T3, thereby avoiding signal interference.

As shown in FIG. 3, in some embodiments, the external pins PIN include a plurality of drain pins DP. Four drain pins DP are illustrated here, but the present invention is not limited to this. The number of the drain pins DP can be adjusted according to the needs of users. The drain pins DP are coupled to the lead frame 30. The second electrode pattern P2 of

each of the power transistor dies 40 is a single and integral drain conductive area (i.e., drain conductive island DI) to represent the drain of the power transistor die 40. For example, the second electrode pattern P2 is a drain conductive island DI which covers the second surface of the power transistor die 40. Thus, the drain pin DP and the drain conductive area of each of the power transistor dies 40 (in other words, the drain of each of the power transistor dies 40) are commonly connected via the lead frame 30.

As shown in FIG. 3, FIG. 4, and FIG. 8, in some embodiments, the sum of a total conductive area of the drain pins DP and a conductive area of the lead frame 30 is substantially the same as that of a total conductive area of the source pins SP and a conductive area of the conductive layer 25 (specifically, the conductive area of the fourth trace T4). Thus, the current sharing effect between the drain and the source of the power transistor die 40 can be realized, thereby improving the performance of the power module 10.

As shown in FIG. 3, in some embodiments, the lead frame 30 has a plurality of fastening members 31. Each fastening member 31 includes a plurality of first openings 311. The first openings 311 are arranged in a straight line. Through the first openings 311, damage caused by the stress effect of the lead frame 30 can be reduced.

As shown in FIG. 7, in some embodiments, the thermal conductive layer 21 has a plurality of second openings 211. The second openings 211 surround the boundary of the thermal conductive layer 21. Through the second openings 211, damage caused by the stress effect of the thermal conductive layer 21 can be reduced.

To sum up, according to some embodiments, a plurality of power transistor dies connected in parallel are integrated into a single power module, so as to save the assembly burden and enhance the stability of high current transmission. In some embodiments, the thermal conductive layer of the present invention can be far away from a circuit board on which the power module is installed, so as to avoid that the heat is accumulated on the circuit board, thereby achieving effective thermal dissipation and lowering the risk of damage of the power module. In some embodiments, the thermal conductive layer is isolated from the conductive layer by the insulating layer in the present invention, so as to achieve the thermoelectric separation effect, thereby lowering the risk of signals being affected.

What is claimed is:

1. A power module, comprising:
a substrate, comprising a thermal conductive layer, an insulating layer, and a conductive layer, wherein the insulating layer is located between the thermal conductive layer and the conductive layer;
a lead frame; and
a plurality of power transistor dies, each of the power transistor dies comprising a first electrode pattern and a second electrode pattern opposite from the first electrode pattern, wherein the first electrode pattern is coupled to the conductive layer, and the second electrode pattern is coupled to the lead frame, thereby connecting the power transistor dies in parallel.

2. The power module according to claim 1, further comprising a package, wherein the substrate, the lead frame and the power transistor dies are encapsulated within the package, the package comprises a first exposed area, and the thermal conductive layer is exposed through the first exposed area.

3. The power module according to claim 2, further comprising a plurality of external pins, wherein the package comprises a second exposed area opposite to the first exposed area, so as to expose the external pins.

4. The power module according to claim 1, further comprising a plurality of gate resistors corresponding to the power transistor dies, wherein each of the first electrode patterns comprises a gate conductive island, each of the gate resistors is coupled to the conductive layer, so as to be connected in series with the gate conductive island of the corresponding first electrode pattern of the power transistor die, and the gate resistors are commonly connected to each other via the conductive layer.

5. The power module according to claim 4, further comprising a ground resistor, wherein each of the first electrode patterns further comprises at least one source conductive island, the ground resistor is coupled to the conductive layer, so as to be connected in series with the at least one source conductive island of the first electrode pattern of one of the power transistor dies, and the ground resistor and the gate resistors are commonly connected to each other via the conductive layer.

6. The power module according to claim 5, further comprising a plurality of external pins, wherein the external pins comprise a gate pin; the conductive layer comprises a trace and a gate pin pad; the gate pin pad is located at a first corner of the substrate and coupled to the gate pin; the trace extends from the first corner along an edge of the substrate to a second corner of the substrate opposite to the first corner; and the trace is coupled to the ground resistor, the gate resistors and the gate pin pad.

7. The power module according to claim 6, wherein the external pins further comprise a plurality of source pins, the conductive layer further comprises a plurality of source pin pads coupled to the source pins and the at least one source conductive island of each of the first electrode patterns of some of the power transistor dies, one of the source pin pads is located at the second corner, and the rest of the source pin pads are located between the trace and the power transistor dies.

8. The power module according to claim 7, wherein each of the source pins coupled to the rest of the source pin pads has a recess, so as to cross over the trace.

9. The power module according to claim 1, further comprising a plurality of external pins, wherein the external pins comprise a plurality of drain pins coupled to the lead frame, and the second electrode pattern is a single and integral drain conductive area.

10. The power module according to claim 9, wherein the external pins further comprise a plurality of source pins, and the sum of a total conductive area of the drain pins and a conductive area of the lead frame is substantially the same as that of a total conductive area of the source pins and a conductive area of the conductive layer.
